(19) United States
(12) Patent Application Publication
(10) Pub. No.: US 2006/0183298 A1
(43) Pub. Date: Aug. 17, 2006

(54) Method for manufacturing a ceramic/metal substrate

(76) Inventors: Jurgen Schulz-Harder, Lauf (DE); Kurt Mitteregger, Wien (AT); Karl Exel, Rimbach (DE); Jurgen Weisser, Jena (DE)

Correspondence Address: HOFFMAN WASSON & GITLER, P.C;CRYSTAL CENTER 2, SUITE 522, 2461 SOUTH CLARK STREET, ARLINGTON, VA, 22202-3843, US

(21) Appl. No.: 10/560,525

(22) PCT Filed: May 14, 2004
(86) PCT No.: PCT/DE04/01012

§ 371 Date: Mar. 14, 2006

(30) Foreign Application Priority Data
Jun. 16, 2003 (DE) 10327360.3

(51) Int. Cl. H01L 21/78; H01L 21/301

(52) U.S. Cl. 438/460

(57) ABSTRACT

The invention relates to a novel method for producing a metal/ceramic substrate, which is characterized by applying at least one metal area to at least one top surface of a ceramic layer. At least one metal area is applied to at least one surface side of a ceramic layer, wherein the ceramic layer is heated in a thermal process step in an area not covered by the metal area along a separating or break-off line.

### BACKGROUND OF THE INVENTION

The invention relates to a method for manufacturing a ceramic-metal substrate.

It is known to apply a metallization forming strip conductors, connectors, etc. to a ceramic, e.g. to an aluminum-oxide ceramic by means of the so-called “DCB process” (direct copper bond technology), said metallization being formed from metal or copper foils or metal or copper sheets, the surfaces of which comprise a layer or a coating (melting layer) resulting from a chemical bond between the metal and a reactive gas, preferably oxygen. In this method, which is described for example in U.S. Pat. No. 3,744,120 and in DE-PS 23 19 854, this layer or coating (melting layer) forms a eutectic with a melting temperature below the melting temperature of the metal (e.g. copper), so that the layers can be bonded to each other by placing the foil on the ceramic and heating all layers, namely by melting the metal or copper essentially only in the area of the melting layer or oxide layer.

This DCB process then comprises, for example, the following process steps:
oxidation of a copper foil so as to produce an even copper oxide layer;
placing the copper foil on the ceramic layer;
heating the composite to a process temperature between approx. 1025 and 1083° C., e.g. to approx. 1071° C.;
cooling to room temperature.

Also known is the so-called active soldering process (DE 22 13 115; EP-A-153 618), in particular for the manufacture of metal-ceramic substrates. In this process, a bond is manufactured at a temperature between ca. 800-1000° C. between a metal foil, for example copper foil, and a ceramic substrate, for example aluminum oxide ceramic, using a hard solder, which in addition to a main component such as copper, silver and/or gold also contains an active metal. This active metal, which is at least one element of the group Hf, Ti, Zr, Nb, Cr, creates a bond between the solder and the ceramic through a chemical reaction, while the bond between the solder and the metal is a metallic hard solder bond.

Also known is the so-called Mo—Mn process or Mo—Mn—Ni process, in which a paste made of Mo—Mn is applied to a ceramic layer and is then baked onto the ceramic to form a metal layer, which then forms the basis for soldering on a metallization, wherein the metal layer preferably is nickel-plated before soldering. A similar known process is referred to as the W process, in which a paste containing tungsten is applied and baked on to form the metallization and basis for subsequent soldering.

Also known is the LTCC (Low Temperature Cofired Ceramic) process, in which a paste containing a conductive metal is applied to a green, i.e. unfired or unsintered ceramic, and baked onto the ceramic during firing. In particular it is also known in this process to arrange a plurality of the unfired ceramic layers provided with the paste in a stack for firing.

Also known in particular are metal-ceramic substrates in the form of a multiple substrate, in which metallizations (metal areas) are provided on a—for example large-surface—common ceramic plate or layer, each metallization being allocated to a single substrate or forming single substrates. Grooves forming break-off lines are then produced in the ceramic layer, for example using a laser, so that the multiple substrate can be separated into single substrates by mechanical breaking along said break-off lines.

There is a certain disadvantage to this method, consisting in the fact that material that vaporizes while the break-off lines are being produced is deposited on the substrate, causing contamination of the multiple substrate, especially of the metal areas, which can impair the further processing.

It is an object of the invention to present a method that eliminates this disadvantage.

### SUMMARY OF THE INVENTION

In the method according to the invention, in which either the ceramic layer is thermally separated or split along the respective processing or separating line by means of the thermal treatment or at least one break-off line is produced by means of the thermal treatment, enabling subsequent separation of the ceramic through mechanical breaking, there is no contamination of the substrate and in particular no formation of bumps or craters through deposits of vaporized material on the substrate along the respective separating or break-off line, so that the further processing of the substrate is not impaired.

### BRIEF DESCRIPTION OF THE DRAWINGS

Exemplary embodiments of the invention are explained below in more detail with reference to the drawings, wherein:

FIG. 1 shows, in a simplified representation in top view, a multiple metal-ceramic substrate with separating lines produced in the ceramic layer between single substrates, manufactured using the method according to the invention;

FIG. 2 shows, in a simplified schematic diagram, an array for implementing the thermal treatment in the method according to the invention;

FIG. 3 shows an enlarged representation of the work area for implementing the thermal treatment of the method according to the invention;

FIG. 4 shows a perspective representation of the respective work area for implementing the thermal treatment of the method according to the invention; and

FIG. 5-7 show schematic representations of various methods for the mechanical breaking of the multiple substrate into single substrates along the respective separating or break-off line.

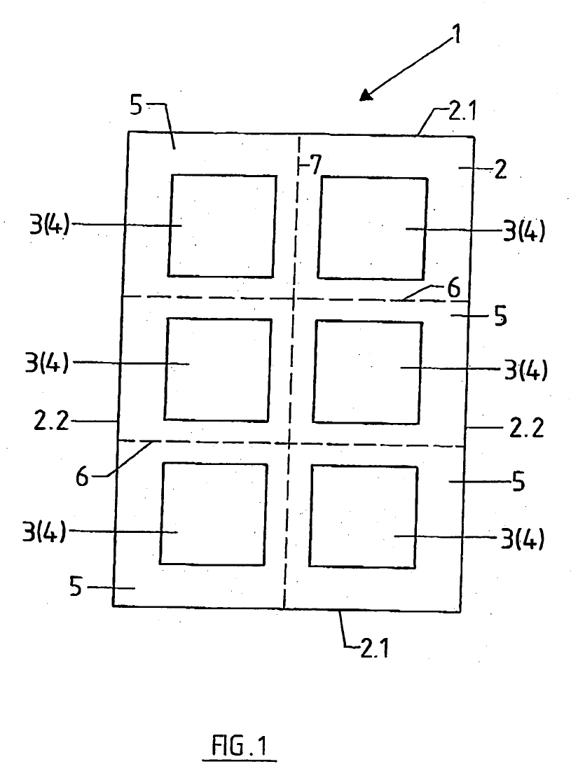

### DETAILED DESCRIPTION OF THE INVENTION

In the drawings, 1 generally designates a metal-ceramic multiple substrate, which is manufactured by providing a large-surface plate made of ceramic or a large-surface ceramic layer 2 with a structured metallization on both surface sides, so that said metallization forms a plurality of metal areas 3 and 4 on both surface sides of the ceramic layer 2. In the depicted embodiment, one metal area 4 on the bottom side of the ceramic layer 2 is located opposite one metal area 3 on the top side of the ceramic layer 2. Each metal area 3 defines, together with the corresponding metal area 4, one single substrate 5.

These single substrates connect with each other via the separating or break-off lines 6 and 7 formed in the ceramic layer 2. The separating or break-off lines 6 and 7 in the depicted embodiment are produced so that the separating or break-off lines 6 extend parallel to the narrow sides 2.1 of the rectangular ceramic layer 2 and the separating line 7 extends parallel to the two long sides 2.2 of the ceramic layer 2. The metal areas 3 and 4 are both at a distance from the edge of the ceramic layer 2 and from the separating and break-off lines 6 and 7.

The single substrates 5 are used for example for circuit boards for electric circuits or modules, for which purpose the metallizations 3 are structured to form strip conductors, contact surfaces, etc.

The ceramic layer 2 is for example made of aluminum oxide, AI₂0₃, or aluminum nitride (AlN) Other ceramics, for example Si₃N₄, SiC, BeO, TiO₂, ZrO₂ or AI₂, o₃ containing ZrO₂, for example between 5-30 percent by weight, and mullite (3Al₂O₃×2 silicon oxide) are also conceivable.

The metallizations 3 and 4 are applied to the ceramic layer 2 for example by means of a high-temperature process, e.g. in the form of a metal or copper foil using the direct-bonding process with the use of a copper foil by means of the DCB process or by active soldering. In a subsequent processing step, the metallizations are then structured in the individual metal areas 3 and 4 by means of masking and etching, for example.

The metal areas 3 and 4 can also be applied individually, for example in the form of foil blanks, to the surface sides of the ceramic layer 2 using the high-temperature process mentioned above. Furthermore, it is possible to manufacture the metal area 3 and/or 4 using thick film technology, i.e. by applying and baking on a suitable electrically conductive paste, etc.

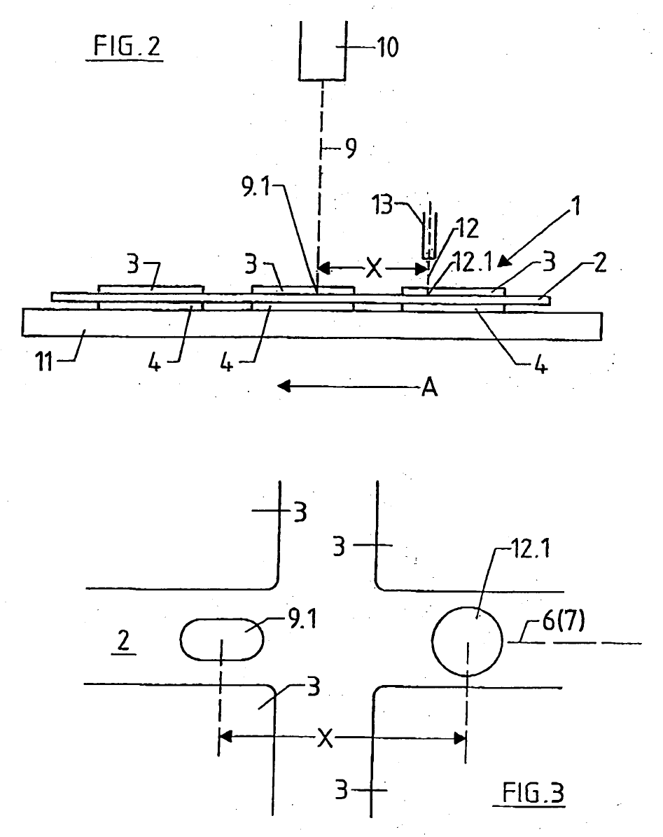

A special feature of the method according to the invention is the production of the separating or break-off lines 6 and 7 in the ceramic layer 2. This special processing step, which is also referred to as thermal processing, is depicted in FIGS. 2-4 and consists essentially in the fact that the ceramic layer 2 is progressively heated and then shock-cooled partially and linearly, thus producing—along the entire processing line or separating and break-off line—a controlled weakening of material or fracture between the top side and bottom side of the ceramic layer 2 within the ceramic layer through mechanical tensions, which occur during heating and subsequent cooling, as shown at 8 in FIG. 4.

The partial heating progressing along the respective separating or break-off line 6 or 7 being produced is effected in the depicted embodiment using a laser beam 9 of a laser 10. In this processing step, the multiple substrate 1 is flat and lies with its surface sides in horizontal planes, held on a clamping surface of a clamping fixture 11, by means of a vacuum on its bottom side.

The laser beam 9 is focused on the top side of the multiple substrate and of the ceramic layer 2 through the lens of the laser 10, in the depicted embodiment in such a manner that the focus 9.1 has an oval cross section where its greater cross section axis is oriented in processing direction A, i.e. in the direction of the separating and break-off line 6 and 7 being produced. This causes the focus 9.1 and the momentary work area formed by this focus to be narrow crosswise to the processing direction A, and wide in the processing direction, so that during the relative movement between the laser beam 9 and the multiple substrate 1 sufficient time is available for sufficient heating of the ceramic layer 2. The relative movement between the laser beam 9 and the multiple substrate 1 in the processing direction is achieved for example by a corresponding movement of the clamping fixture 11.

The energy of the laser beam 9 is adjusted, taking into consideration various parameters, e.g. in particular the thickness of the ceramic layer 2, the type of material used for said ceramic layer and the speed of the relative movement between the laser beam 9 and the multiple substrate 1 in the processing direction, so that although optimum heating of the ceramic is effected for the desired purpose, there is no change or no perceptible change in the surface of the ceramic layer 2.

The heating of the multiple substrate 1 and of the ceramic layer 2 along the separating or break-off lines 6 and 7 can be also achieved with other methods, for example using a hot gas beam, a flame or a plasma, or by applying microwave energy to the ceramic layer 2.

Following the laser beam 9 or the momentary processing area in the processing direction A by a distance x, a stream 12 of a coolant is applied to the ceramic layer 2 for the purpose of cooling, so that this shock-cooling causes the formation of a fracture 8. Suitable coolants are for example cooled air or a cooled gas, which is emitted from a jet 13 located above and aimed at the ceramic layer 2. Suitable coolants also include such gases or gas mixtures (e.g. CO₂), which are fed to the jet 13 under pressure and cool at this jet through expansion. Also suitable for cooling are various liquids, such as water, or liquid gas and/or air-gas mixtures, e.g. in the form of an aerosol.

The distance x and the type and quantity of the cooling medium likewise are adjusted taking into consideration various parameters, e.g. the feed rate or processing rate, the thermal energy applied and stored in the ceramic layer 2 with the laser beam 9, the thickness and type of ceramic, the type of coolant, etc., in order to produce the desired fracture 8.

The thickness of the ceramic layer 2 in the depicted embodiment is between 0.1 and 3 mm. The thickness of the metal areas 3 and 4 is dependent for example on how these metal areas are produced and is between 0.002 and 0.6 mm. If the metal areas 3 and 4 are produced using a metal foil, for example a copper foil, and using the DCB process or the active soldering process, the thickness of the metal areas is for example between 0.1-0.6 mm.

The distance between the metal areas 3 and 4 on each surface side of the ceramic layer is on the order of approximately 0.1-3 mm, so that said metal areas 3 and 4 are at a distance of approximately 0.05-1.5 mm from the respective separating or break-off line 6 and 7.

After producing the separating and break-off lines 6 and 7 in the ceramic layer 2, various possibilities exist for the further processing of the multiple substrate 1. For example, it is possible to further structure this multiple substrate 1 at the metal areas 3 to form strip conductors, contact surfaces, etc. using the usual technologies, if this has not already been done, and/or to provide the metallizations 3 and 4 with an additional metal layer on the surfaces, for example nickel-coating, and to mount electric components on the multiple substrate 1 or the metal areas 3 that are structured there. Afterwards, the multiple substrate 1 is separated into the single substrates 5 already equipped with the components, i.e. into the circuits formed by these by means of mechanical breaking along the separating or break-off lines 6 and 7.

It is also fundamentally possible to separate the multiple substrate 1 along the separating or break-off lines 7 by breaking it into single substrates 5 before mounting the components and then to process the substrates individually.

FIG. 5 shows a possibility for separating the multiple substrate into the single substrates 5 by breaking. The multiple substrate 1 is supported at the corresponding separating or break-off line 6 and 7 with a force P on one surface side, for example on the bottom side, while a force ½ P is applied to the top of the multiple substrate 1, on both sides and at a distance from the separating or break-off line 6 and 7, so that the flexural load exerted on the ceramic layer produces a clean separation along the respective separating or break-off line 6 and 7.

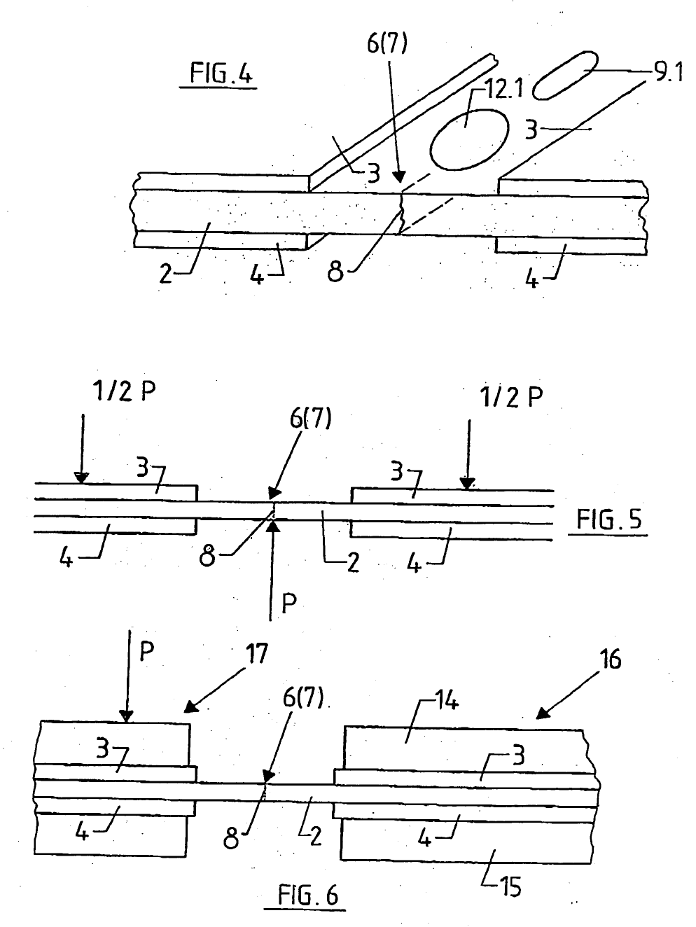

FIG. 6 shows a further possibility for breaking the multiple substrate 1 into the single substrates 5. The multiple substrate 1 is clamped along the respective separating and break-off line 6 and 7 on one side between the clamps 14 and 15 of a fixture 16 at a distance from the respective separating or break-off line, so that the metal areas 3 and 4 also are held by the clamps 14 and 15. On the side of the separating or break-off line 6 and 7 opposite of the holder 16, the force P is exerted via a further clamp fixture 17 on the multiple substrate, so that the latter likewise breaks along the separating or break-off line.

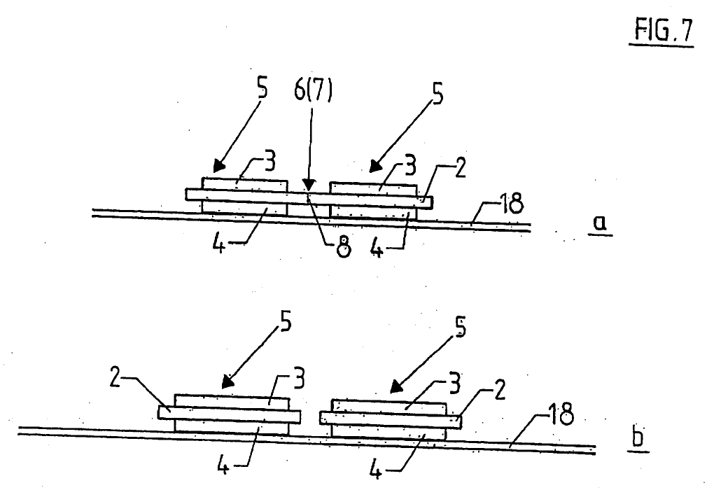

FIG. 7 shows in positions a and b a further, particularly efficient possibility for separating the multiple substrate 1 into the single substrates 5 by breaking. In this process, the multiple substrate 1 is fixed with its bottom side or with the metal areas 4 there on a self-adhesive foil 18, for example on a so-called blue foil, as used in the manufacture of semiconductors. The multiple substrate is then separated on this foil 18 by breaking it into the single substrates 5. In order to increase the space between the single substrates 5 to facilitate further processing, the foil 18 is stretched (position b).

The invention was described above based on exemplary embodiments. It goes without saying that numerous modifications and variations are possible without abandoning the underlying inventive idea upon which the invention is based.

It was assumed above that the thermal treatment, i.e. the heating and subsequent cooling of the ceramic layer 2, produces the separating or break-off lines 6 and 7 in the form of a fracture 8 and that breaking of the multiple substrate 1 into the single substrates 5 takes place at a later time. Through a suitable adjustment of the process parameters, in particular of the thermal treatment, the thermal separation or thermal splitting of the ceramic layer 2 can be achieved without subsequent mechanical breaking, without the burning or vaporization of ceramic material in the area of the respective separating line.

### LIST OF REFERENCE NUMBERS

1 multiple substrate
2 ceramic layer
3,4 metal areas
5 single substrate
6,7 separating or break-off line
8 fracture
9 laser beam
9.1 focus of beam
10 laser
11 clamping fixture for multiple substrates
12 cooling stream
13 cooling jet
14, 15 clamp
16 clamp fixture
17 clamp fixture
18 self-adhesive foil
A processing or feed mechanism
P force
X distance between center of focus 9.1 and center of the cooling area 12.1 formed by the cooling stream 12

What is claimed is:

1-26. (canceled)

27. A method for manufacturing a metal-ceramic substrate, in which a metallization forming a plurality of metal areas is applied to at least one surface side of a ceramic layer, and in which, after application of the metal areas, the ceramic layer is heated, in a thermal treatment or process step, in the areas not covered by the metal areas in order to produce separating or break-off lines between the metal areas, wherein the heating of the ceramic layer during the thermal treatment or process step takes place progressively and without vaporization or burning of the ceramic material in a treatment area that moves in relation to the ceramic layer, and that after the heating process the ceramic is progressively shock-cooled so that a controlled fracture or weakening of material is effected in the ceramic layer in order to produce the separating or break-off line.

28. The method according to claim 27, wherein the metal area of said metallization being bonded with the ceramic layer by means of direct copper bond bonding or an active soldering process.

29. The method according to claim 27, wherein the at least one metal area is produced using a thick film process or a thick film technology.

30. The method according to claim 27, wherein the at least one metal area is produced using the Mo—Mn process, a W process, an LTCC process, or a combination thereof.

31. The method according to claim 27, wherein the heating of the ceramic layer during the thermal treatment or process step is effected by means of an energy beam or a laser beam.

32. The method according to claim 31, wherein the laser beam is focused in order to form an oval focus, with its greater cross-section axis oriented in the processing direction (A).

33. The method according to claim 27, wherein the ceramic layer is thermally separated or split along the respective separating line by means of the thermal treatment or process step.

34. The method according to claim 27, wherein a break-off line is produced in the ceramic layer by means of the thermal treatment or process step, enabling subsequent controlled mechanical breaking of the ceramic layer.

35. The method according to claim 27, wherein the heating of the ceramic layer is effected by means of a hot gas beam, a flame, a plasma, or microwave energy.

36. The method according to claim 27, wherein the cooling of the ceramic layer is effected progressively at a pre-defined spatial and/or temporal distance (x) from the heating.

37. The method according to claim 27, wherein the treatment of the ceramic layer is effected with the coolant progressively and point by point.

38. The method according to claim 37, wherein the coolant is applied to the ceramic layer in the form of at least one coolant stream.

39. The method according to claim 37, wherein the coolant is a liquid medium, water, a gaseous or vaporous medium, an aerosol, or a mixture of these.

40. The method according to claim 27, wherein the ceramic layer is held in a clamping fixture during the thermal treatment or process step, by means of a vacuum.

41. The method according to claim 27, wherein the ceramic layer or the metal-ceramic substrate formed by said layer is located on a self-adhesive foil for separation into single substrates.

42. The method according to claim 27, wherein the thermal treatment is effected along a groove produced on at least one surface side of the ceramic layer.

43. The method according to claim 27, wherein at least one metal area is applied to both surface sides of the ceramic layer.

44. The method according to claim 27, wherein the ceramic layer is part of a multiple substrate, that a plurality of metal areas, each allocated to one single substrate, are provided on at least one surface side of the ceramic layer, and that the separating or break-off lines are produced between the single substrates through the thermal treatment or process step.

45. The method according to claim 27, wherein the ceramic layer is selected from the mullite group, AI₂O₃, AlN, Si₃N₄, SiC, BeO, TiO₂, ZrO₂, or AI₂O₃ with a ZrO₂ content.

46. The method according to claim 27, wherein the ceramic layer has a thickness between 0.1 and 3 mm.

47. The method according to claim 27, wherein the at least one metal area has a thickness between 0.02 and 0.6 mm, or a thickness between 0.1 and 0.6 mm.

48. The method according to claim 27, wherein in the case of a plurality of metal areas on one surface side of the ceramic layer, said metal areas are at a distance of 0.1-3 mm from each other.

49. The method according to one claim 27, wherein the metal areas are manufactured at least partially from a metal layer or foil, a copper layer or foil, using a direct bonding process or an active soldering process.
